(19) United States
(12) Patent Application Publication
(10) Pub. No.: US 2025/0204117 A1
(43) Pub. Date: Jun. 19, 2025

(54) LIGHT EMITTING DISPLAY DEVICE HAVING IMPROVED THERMAL RESISTANCE

(71) Applicant: LG Display Co., Ltd., Seoul (KR)

(72) Inventors: Byung-Gwan HYUN, Paju-si (KR); Won-Rae KIM, Paju-si (KR); Hye-Jeong PARK, Paju-si (KR)

(73) Assignee: LG Display Co., Ltd., Seoul (KR)

(21) Appl. No.: 18/932,356

(22) Filed: Oct. 30, 2024

(30) Foreign Application Priority Data
Dec. 15, 2023 (KR) 10-2023-0183109

(51) Int. Cl. H01L 33/64; H01L 25/075

(52) U.S. Cl. CPC H10H 20/8581; H01L 25/0753; H10H 20/8582; H10H 20/8583

(57) ABSTRACT

A light emitting display device can include a heat dissipater having a first heat dissipating particle and extending from an outside of a first electrode constituting a light emitting diode disposed in an emission area. Further, optionally, the display device can further include a bank layer disposed in a non-display area and having a light absorbing material and a second heat dissipating particle. Each of the heat dissipater and the bank layer can include the heat dissipating particle so that heat generated in the light emitting diode can be dissipated outwardly. In addition, as the amount of the light absorbing material contents in the bank layer decrease, the credibility of the light emitting display device can be improved.

### CROSS-REFERENCE TO RELATED APPLICATIONS

This application claims priority under 35 U.S.C. § 119 (a) to Republic of Korea Patent Application No. 10-2023-0183109, filed in the Republic of Korea on Dec. 15, 2023, the entire contents of which are hereby expressly incorporated by reference into the present application.

### BACKGROUND

### Technical Field

The present disclosure relates to a light emitting device, and more particularly to, a light emitting display device with beneficial luminous properties and heat resistance.

### Discussion of the Related Art

Flat display devices comprising light emitting diodes (LEDs) have been investigated as display devices that can replace a liquid crystal display device (LCD). The LED can be fabricated as thin film, and the electrode configurations in the LED can implement unidirectional or bidirectional images. Further, the LED can be formed even on a flexible transparent substrate such as a plastic substrate so that a flexible or foldable display device can be realized with ease using the LEDs. In addition, the LED can be driven at a lower voltage and the LED has advantageous high color purity compared to the LCD.

The LED emits light as holes injected from anode and electrons injected from cathode are recombined within an emitting material layer to generate excitons of unstable energy state, and the excitons convert to a stable ground state. However, materials in the LED can be deteriorated due to the heat generated when driving the LED. Accordingly, the luminous efficiency and luminous lifetime can be lowered.

### SUMMARY OF THE DISCLOSURE

Accordingly, some embodiments of the present disclosure are directed to a light emitting display device that substantially obviates one or more of the problems due to the limitations and disadvantages of the related art.

An aspect of the present disclosure is to provide a light emitting display device with beneficial processibility, reliability and stability.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, in one aspect, the present disclosure provides a light emitting display device that comprises a substrate having an active area comprising a pixel region, and a non-display area surrounding the active area; a thin film transistor disposed in the pixel region on the substrate; a light emitting diode comprising a first electrode connected to a drain electrode of the thin film transistor; and a heat dissipater extended outwardly from the first electrode, wherein the heat dissipater can comprises a first heat dissipating particle.

According to one or more aspects of the present disclosure, the first heat dissipating particle can comprise any one of metal material of gold (Au), copper (Cu), silver (Ag), or any combination thereof; carbon-containing material of graphite, graphene, carbon nanotube (CNT), or any combination thereof; any one inorganic oxide material of Al₂O₃, SiO₂, MgO, ZnO, ZrO₂, or any combination thereof; any one inorganic nitride of aluminum nitride (AlN), boron nitride (BN), or any combination thereof; boron arsenide (BAs); or any combination thereof.

According to one or more aspects of the present disclosure, the first heat dissipating particle can comprise boron nitride.

According to one or more aspects of the present disclosure, as an example, the first heat dissipating particle can comprise any one of boron nitride nanotube (BNNT), boron nitride nanowire, boron nitride nanosheet (BNNS), hexagonal boron nitride (h-BN), cubic boron nitride (c-BN), or any combination thereof.

According to one or more aspects of the present disclosure, the first heat dissipating particle can comprise any one of a nanoparticle, a nanotube, a nanowire, a nanosheet, or any combination thereof.

According to one or more aspects of the present disclosure, the first heat dissipating particle can comprise the nanoparticle, and at least one of the nanowire and the nanosheet.

According to one or more aspects of the present disclosure, as an example, each of the nanowire and the nanosheet can have an aspect ratio of about 100 to about 10,000.

In an embodiment of the present disclosure, the light emitting display device can further comprise a bank layer surrounding a periphery of the first electrode for each pixel region.

According to one or more aspects of the present disclosure, the bank layer can comprise a light absorbing material and a second heat dissipating particle.

According to one or more aspects of the present disclosure, as an example, the light absorbing material and the second heat dissipating particle in the bank layer can be mixed with a weight ratio between about 8:2 and about 2:8.

According to one or more aspects of the present disclosure, the second heat dissipating particle can comprise any one of metal material of gold (Au), copper (Cu), silver (Ag), or any combination thereof; carbon-containing material of graphite, graphene, carbon nanotube (CNT), or any combination thereof; any one inorganic oxide material of Al₂O₃, SiO₂, MgO, ZnO, ZrO₂, or any combination thereof; any one inorganic nitride of AlN, boron nitride (BN), or any combination thereof; boron arsenide (BAs); or any combination thereof.

According to one or more aspects of the present disclosure, the second heat dissipating particle can comprise boron nitride.

For example, the second heat dissipating particle can comprise any one of boron nitride nanotube (BNNT), boron nitride nanowire, boron nitride nanosheet (BNNS), hexagonal boron nitride (h-BN), cubic boron nitride (c-BN), or any combination thereof.

According to one or more aspects of the present disclosure, the second heat dissipating particle can comprise any one of a nanoparticle, a nanotube, a nanowire, a nanosheet, or any combination thereof.

For example, the second heat dissipating particle can comprise the nanoparticle, and at least one of the nanowire and the nanosheet.

According to one or more aspects of the present disclosure, each of the nanowire and the nanosheet can have an aspect ratio of about 100 to about 10,000.

In one embodiment, the heat dissipater can be extended to a pad portion disposed in the non-display area from the outside of the first electrode.

As an example, the heat dissipater can be extended outwardly in a linear form in the active area of the outside of the first electrode, and can be randomly disposed in a pad area comprising the pad portion.

In another embodiment, the heat dissipater can be extended toward a driver disposed in the non-display area from the outside of the first electrode and a heat dissipating adhesive can be interposed between an end of the heat dissipater and the driver.

According to one or more aspects of the present disclosure, the light emitting diode can further comprise a second electrode facing the first electrode; and an emissive layer disposed between the first electrode and the second electrode, and the emissive layer can comprise one or more emitting material layers.

In one or more embodiments, the heat dissipater comprising the first heat dissipating particle is extended from the outside of the first electrode constituting the light emitting diode so that heat can be transferred outwardly, and the stability of the light emitting diode and the light emitting display device can be improved.

According to one or more aspects of the present disclosure, the bank layer disposed in the non-display area and defining each pixel region comprises the light absorbing material and the second heat dissipating particle. As the contents of the light absorbing material in the bank layer decreases, the processibility and the reliability of the light emitting diode can be improved.

According to one or more aspects of the present disclosure, it is possible to prevent various materials included in the light emitting display device, such as luminous materials and/or charge transferring materials in the light emitting diode from being degraded or deteriorated caused by heat. Therefore, the luminous lifetime of the light emitting diode and the light emitting display device can be improved.

It is to be understood that both the foregoing general description and the following detailed description are exemplary and explanatory, and are intended to provide further explanation of the inventive concepts as claimed.

### BRIEF DESCRIPTION OF THE DRAWINGS

The accompanying drawings, which are comprised to provide a further understanding of the disclosure, are incorporated in and constitute a part of this application, illustrate embodiments of the disclosure and together with the description serve to explain principles of the disclosure.

FIG. 1 illustrates a schematic circuit diagram of a light emitting display device in accordance with one or more embodiments of the present disclosure.

FIG. 2 illustrates a schematic plan view of a light emitting display device in accordance with one or more embodiments of the present disclosure.

FIG. 3 illustrates a cross-sectional view taken along line III-III in FIG. 2.

FIG. 4 illustrates a drawing extending portion “A” in FIG. 3.

FIG. 5 is a diagram illustrating schematically heat transfer path in a heat dissipater in accordance with one embodiment of the present disclosure.

FIG. 6 is a diagram illustrating schematically heat transfer path in a bank layer in accordance with another embodiment of the present disclosure.

FIGS. 7A to 7D illustrate a process of disposing the heat dissipater extending outwardly from a first electrode of the light emitting diode using an electrospinning process in accordance with an embodiment of the present disclosure.

FIGS. 8A and 8B illustrate a process of disposing the heat dissipater extending outwardly from the first electrode of the light emitting diode using a printing process in accordance with another embodiment of the present disclosure.

FIGS. 9 to 12 each show a photograph illustrating colors of the patterned bank layer prepared in accordance with Example and Comparative Examples.

### DETAILED DESCRIPTION OF THE EMBODIMENTS

Reference will now be made in detail to aspects of the disclosure, examples of which are illustrated in the accompanying drawings. Wherever possible, the same reference numbers will be used throughout the drawings to refer to the same or like parts. Further, the term “can” fully encompasses all the meanings and coverages of the term “may.”

All the components of each light emitting display device according to all embodiments of the present disclosure are operatively coupled and configured.

The present disclosure relates to a light emitting display device that comprises a heat dissipater comprising a first heat dissipating material and extended outwardly from a first electrode of a light emitting diode, and optionally, a bank layer disposed in a non-display area and comprising a light absorbing material and a second heat dissipating material. The light emitting display device in accordance with the present disclosure will be described.

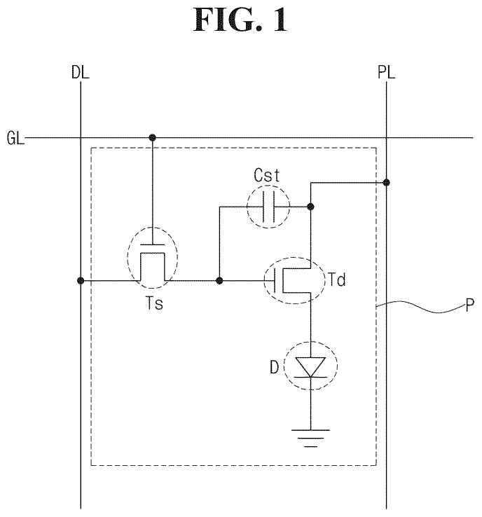

FIG. 1 illustrates a schematic circuit diagram of a light emitting display device in accordance with one or more embodiments of the present disclosure.

As illustrated in FIG. 1, a gate line GL, a data line DL and power line PL, each of which crosses each other to define a pixel region P, are provided in a light emitting display device. A switching thin film transistor Ts, a driving thin film transistor Td, a storage capacitor Cst and a light emitting diode D are disposed within the pixel region P. The pixel region P can comprise a first pixel region, a second pixel region, a third pixel region, and optionally a fourth pixel region. For example, the first pixel region can be a red (R) pixel region, the second pixel region can be a green (G) pixel region, the third pixel region can be a blue (B) pixel region, and the fourth pixel region can be a white (W) pixel region. However, embodiments of the present disclosure are not limited to such examples. The light emitting display device can comprise a plurality of such pixel regions P which can be arranged in a matrix configuration or other configurations.

The switching thin film transistor Ts is connected to the gate line GL and the data line DL. The driving thin film transistor Td and the storage capacitor Cst are connected between the switching thin film transistor Ts and the power line PL. The light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

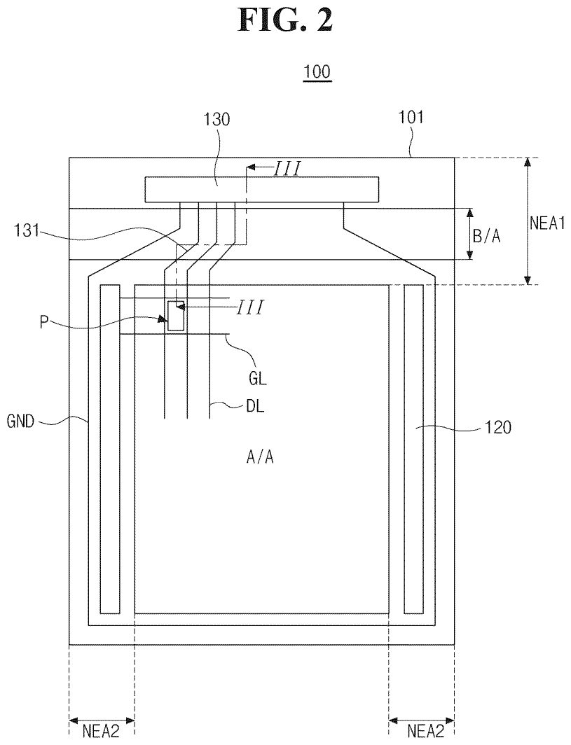

The driving thin film transistor Td is turned on by the data signal applied to a gate electrode 130 (FIG. 2) so that a current proportional to the data signal is supplied from the power line PL to the light emitting diode D through the driving thin film transistor Td. And then, the light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the light emitting display device can display a desired image.

FIG. 2 illustrates a schematic plan view of a light emitting display device in accordance with one or more embodiments of the present disclosure.

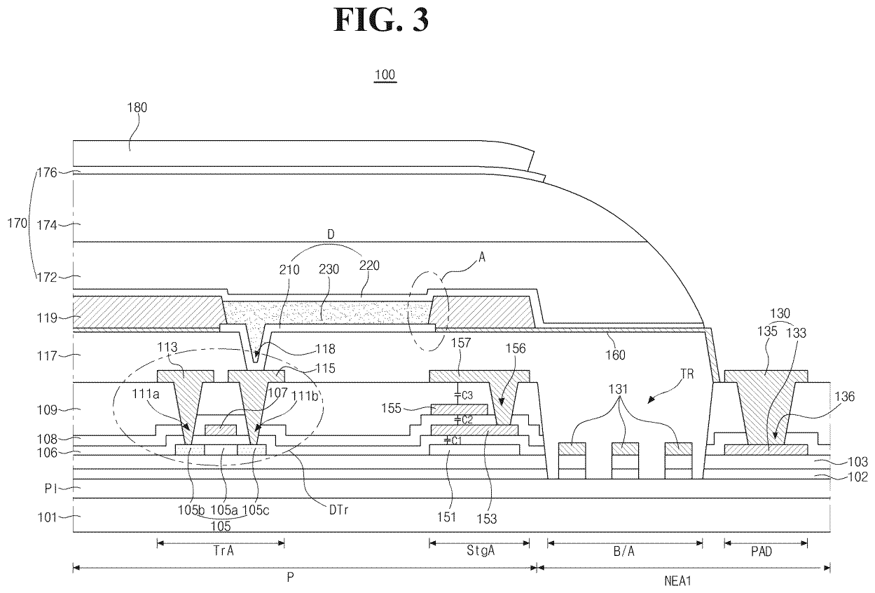

As illustrated in FIG. 2, a light emitting display device 100 comprises a transparent flexible substrate (or substrate) 101, a thin film transistor DTr (FIG. 3) disposed on the flexible substrate 101 and a light emitting diode D (FIG. 3) connected to the thin film transistor DTr to form an array substrate.

A central active area A/A, and non-display areas NEA1 and NEA2 along a periphery or an edge of the active area A/A are defined in the flexible substrate 101. The active area AA is an area where the light emitting diode D (FIG. 3) is disposed, and indicates an area where images are substantially displayed, and can be referred as a display area.

Plural gate line GLs and plural data lines DLs cross each other in the active area A/A to define plural pixel regions Ps. The thin film transistor DTr (FIG. 3) connected to the light emitting diode D (FIG. 3) is disposed in each pixel region P. The driving of the thin film transistor DTr (FIG. 3) is associated with a driver 120 disposed in the non-display areas NEA1 and NEA2, and the thin film transistor DTr (FIG. 3) controls driving current amount provided to the light emitting diode D (FIG. 3).

The non-display areas NEA1 and NEA2 surrounding the periphery of the active area A/A can be divided to a first non-display area NEA1 disposed on a top of the active area A/A and comprising a pad portion 130, and a second non-display area NEA2 located at left and right sides of the active area A/A and comprising the driver 120.

The driver 120 disposed in the second non-display area NEA2 of the flexible substrate 101 provide a driving signal to the thin film transistor DTr (FIG. 3). As an example, the driver 120 can be a gate driver proving a gate signal to the thin film transistor DTr (FIG. 3).

The gate driver can include various gate driving circuits. In one embodiment, the gate driving circuits can be disposed directly on the flexible substrate 102, and such a driver 120 can be referred to GIP (gate-in-panel). In another embodiment, the gate driver can be formed simultaneously together with the display didoes disposed within the active area A/A. while the gate drivers are disposed in both sides of the active area A/A in FIG. 2, the gate driver can be disposed only one side of the active area A/A.

In one embodiment, a data driver proving the data signal to the thin film transistor DTr (FIG. 3) can be mounted on an isolated Printed Circuit Board (PCB), and can be connected to the pad portion 130 disposed in the first non-display area NEA1 of the flexible substrate 101 through a circuit film such as flexible printed circuit board (FPG) 126, and/or the like. In another embodiment, the data driver can be mounted on a circuit film by a type such as COF (chip-on film), COG (Chip-on Glass), COP (Chip-on Plastic), TCP (tape-carrier-package), and the like, and can be connected to the pad portion 130 of the flexible substrate 101.

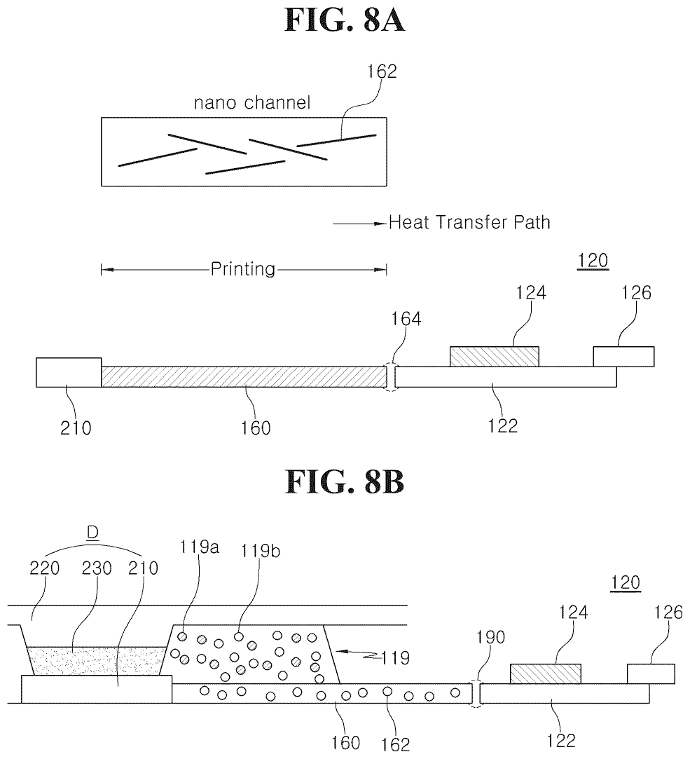

As an example, the data driver of the COF type can comprise, but is not limited to, a film substrate 122 (FIG. 8A) disposed on the flexible substrate 101, a display driver IC (DDIC) 124 (FIG. 8A) disposed on the film substrate 122, and an FPCB 126 (FIG. 8A) disposed on an outside of the film substrate 126 (FIG. 8A). The pad portion 130 can be connected to the circuit film such as FPCB and act as contact terminal connecting the circuit film and a wire 131.

A ground wire GND is arranged surrounding the active area A/A. As an example, the ground wire GND can be arranged surrounding the outside of the gate driver. The ground wire GND is connected to the data driver. The data driver is connected to the outside, and the ground voltage applied from the outside is supplied to the ground wire GND through a ground pad of the data driver.

The first non-display area NEA1 on the flexible substrate 101 includes an area in which wires 131 connecting the pad portion 130 and the active area AA are provided. The wires 131 provides various electrical signals transferred through the pad portion 130 provides to the thin film transistor DTr (FIG. 3) disposed on the active area A/A. In one embodiment, the first non-display area NEA1 where the pad portion 130 is located is bent to the backside of the active area AA to reduce a bezel area. Accordingly, the flexible light emitting display device 100 can be implemented in which only the active area AA and the second non-display area NEA2 are recognized form the front view.

For this purpose, a bending area B/A is defined between the active area A/A and the pad portion 130. Accordingly, the width of the second non-display area NEA2 where the driver 120 is located is significantly reduced in the flexible light emitting display deice 100.

FIG. 3 illustrates a cross-sectional view taken along line III-III in FIG. 2. The light emitting display device 100 can be divided into a top-emission type and a bottom-emission type depending upon the transmission direction of the emitted light. Hereinafter, the light emitting display device 100 of the top-emission type will be described.

As illustrated in FIG. 3, the light emitting display device 100 comprises the flexible substrate 101 defining a pixel region P, and a thin film transistor DTr and a light emitting diode D each of which is disposed in the pixel region P. The light emitting display device 100 comprises a bank layer 119 disposed correspondingly to a non-emission area among the light emitting diodes D to define each pixel region P, and a heat dissipater 160 extended outwardly from the light emitting diode D.

The active area A/A (FIG. 2) and the non-display areas NEA1 and/or NEA2 can be defined in the flexible substrate 101. The active area A/A (FIG. 2) is an area where the pixel region P is arranged and images are displayed from the light emitting diode D. The first and second non-display areas NEA1 and NEA2 are areas other than the active area AA (FIG. 1) and are areas where various circuits, wires and the likes for driving the pixel region P are arranged.

In addition, for convenience of explanation, the area where the thin film transistor (DTr) is located in the active area AA (FIG. 1) is referred to as a switching area TrA, and the area where the storage capacitors C1, C2, and C3 are located in the active area AA is referred to as a storage area StgA. In addition, the area where bending occurs in the first non-display area NEA1 is referred to as the bending area B/A, the area where the pad portion 30 located is located in the first non-display area NEA1 is referred to as a pad area PAD, and the area where the driver 120 (FIG. 2) is located in the second non-display area NEA2 can be referred to as a driving area DA.

For example, considering the convenience of manufacturing, the flexible light emitting display device 100 is formed on a rigid substrate, and then the rigid substrate is isolated from the flexible light emitting display device 100. For example, a sacrificial layer is applied on a rigid substrate, and this sacrificial layer can be formed by depositing amorphous silicon (a-Si). An organic layer PI is applied on the sacrificial layer, and the organic layer PI can include, but is not limited to, a polyimide material with beneficial high-temperature properties. The sacrificial layer is removed by a later irradiated laser, causing the rigid substrate and the organic layer PI to peel off from each other, and then a flexible film substrate or a flexible substrate 101 is attached to the lower surface of the exposed organic layer PI.

The flexible substrate 101 can comprise flexible plastics. For example, the flexible substrate 101 can comprise, but is not limited to, a thin film polymer plastic such as polyimide (PI), polyether sulfone (PES), polyethylene naphthalate (PEN), polyethylene terephthalate (PET), and polycarbonate (PC). Alternatively, the substrate 101 can be a glass substrate.

As an example, the flexible substrate 101 can have a thickness, but is not limited to, about 5 μm to about 50 μm to have excellent flexibility. when the flexible substrate 101 has a thickness of less than 5 μm, the flexible substrate 101 can be easily torn. When the flexible substrate 101 has a thickness exceeding 50 μm, the flexible substrate 101 may not be easily bent.

A multi-buffer layer 102 can be disposed on the organic layer PI. The multi-buffer layer 102 can be a buffer layer in which plural thin films are sequentially stacked. As an example, the multi-buffer layer 102 can be alternately stacked with silicon nitride (SiNₓ) and silicon oxide (SiOₓ) (0<X≤2). Alternatively, the multi-buffer layer 102 can be disposed by repeatedly stacking organic and inorganic layers alternately. The multi-buffer layer 102 can act as an encapsulation layer to prevent external moisture and the likes from penetrating from the organic layer PI.

An active buffer 103 layer can be further disposed on the multi-buffer layer 102. The active buffer layer 103 is intended to protect a semiconductor layer 105 of the thin film transistor DTr and blocks defects flowing from the organic layer PI. As an example, the active buffer layer 103 can comprise the same material as the multi-buffer layer 102.

In one embodiment, bottom shield metal can be disposed between the multi-buffer layer 102 and the active buffer layer 103 under the semiconductor layer 105. The bottom shield metal can comprise molybdenum (Mo).

The thin film transistor DTr is disposed on the active buffer layer 103 in the switching area TrA. In one embodiment, the semiconductor layer 105 can comprise, but is not limited to, oxide semiconductor materials. In this case, a light-shield pattern can be disposed under the semiconductor layer 105, and the light-shield pattern can prevent light from being incident toward the semiconductor layer 105, thereby, preventing or reducing the semiconductor layer 105 from being degraded by the light.

In another embodiment, the thin film transistor DTr can be a thin film transistor using poly-silicon material as an semiconductor layer 105, and can be LPTS thin film transistor using Low Temperature Poly-Silicon (LTPS). Polysilicon materials have high mobility, low energy consumption and excellent reliability. In this case, the semiconductor layer 105 constituting the LTPS thin film transistor disposed on the active buffer layer 103 in the switching region TrA comprises a channel region 105a where a channel is formed when the thin film transistor DTr is driven, a source region 105b and a drain region 105c on both sides of the channel region 105a. The channel region 105a, the source region 105b, and the drain region 105c are defined by ion doping (impurity doping).

An active pattern 151 is disposed in the storage area StgA. The active pattern 151 can include amorphous silicon as the semiconductor layer 105 and can be doped with impurities.

A gate insulating layer 106 comprising an insulating material is disposed on the semiconductor layer 105. The gate insulating layer 106 can comprise, but is not limited to, an inorganic insulating material such as silicon oxide (SiOₓ, wherein 0<x≤2) or silicon nitride (SiNₓ, wherein 0<x≤2).

A gate electrode 107 made of a conductive material such as a metal is disposed on the gate insulating layer 106 corresponding to the switching area TrA so as to correspond to a center, for example, the channel area 105a of the semiconductor layer 105. While the gate insulating layer 106 is disposed on the entire area of the flexible substrate 101 as shown in FIG. 3, the gate insulating layer 106 can be patterned identically as the gate electrode 107. A first metal pattern 153 is disposed on the gate insulating layer 106 correspondingly to the active pattern 151 in the storage area StgA.

The gate electrode 107, the gate line GL (FIG. 1) and the first metal pattern 153 can be made of the same material. As an example, each of the gate electrode 107, the gate line GL and the first metal pattern 153 can independently comprise, but is not limited to, low-resistant metal such as aluminum (Al), aluminum alloy (e.g., AlNd), copper (Cu), copper alloy, molybdenum (Mo), moly titanium (MoTi), chrome (Cr), titanium (Ti), or any combination thereof. Each of the gate electrode 107, the gate line GL and the first metal pattern 150 can have a single-layered structure or a multiple-layered structure such as a dual-layered structure and/or a triple-layered structure.

A first interlayer insulating layer 108 comprising an insulating material is disposed on the gate electrode 107, the gate line GL (FIG. 1) and the first metal pattern 153 and covers an entire surface of the flexible substrate 101. The first interlayer insulating layer 108 can comprise, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

A second metal pattern 155 corresponding to the first metal pattern 153 is disposed on the first interlayer insulating layer 108 in the storage area StgA. The second metal pattern 155 can comprise, but is not limited to, Al, Cu, Mo, Cr, Ni, W and/or alloys thereof. The second metal pattern 155 can have a single-layered structure or a multi-layered structure.

A second interlayer insulating layer 109 is disposed on the first interlayer insulating layer 108 and the second metal pattern 155. The second interlayer insulating layer 109 can comprise, but is not limited to, an inorganic insulating material such as silicon oxide (SiOₓ, wherein 0<x≤2).

Each of the gate insulating layer 106 and the first and second interlayer insulating layers 108 and 109 has first and second semiconductor contact holes 111a and 111b that exposes or do not cover the source area 105b and the drain area 105c of the semiconductor layer 105 in the switching area TrA, and a contact hole 156 that exposes or do not cover a portion of the first metal pattern in the storage area StgA. The first and second semiconductor contact holes 111a and 111b are spaced apart from the gate electrode 107 on both sides of the gate electrode 107. The first and second semiconductor layer contact holes 111a and 111b are formed within the gate insulating layer 106. Alternatively, in certain embodiments, the first and second semiconductor layer contact holes 111a and 111b can be formed only within the first and second interlayer insulating layers 108 and 109 when the gate insulating layer 106 is patterned identically as the gate electrode 107.

A source electrode 113 and a drain electrode 115 are disposed on the first and second interlayer insulating layers 108 and 109 correspondingly to the switching area TrA. The source electrode 113 and the drain electrode 115 are spaced apart from each other on opposing sides of the gate electrode 107, and contact the source area 105b and the drain area 105c of the semiconductor layer 105 through the first and second semiconductor layer contact holes 111a and 111b, respectively. Each of the source electrode 113 and the drain electrode 115 can comprise, but is not limited to, low-resistant metal such as Al, aluminum alloy (e.g., AlNd), Cu, copper alloy, Mo, MoTi, Cr, Ti, or any combination thereof.

The semiconductor layer 105, the gate electrode 107, the source electrode 113 and the drain electrode 115 constitute the thin film transistor DTr, which acts as a driving element. The thin film transistor DTr in FIG. 3 has a coplanar structure in which the gate electrode 107, the source electrode 113 and the drain electrode 115 are disposed on the semiconductor layer 105. Alternatively, the thin film transistor DTr can have an inverted staggered structure in which a gate electrode is disposed under a semiconductor layer and a source and drain electrodes are disposed on the semiconductor layer. In this case, the semiconductor layer can comprise amorphous silicon.

In addition, a third metal pattern 157 is disposed on the second interlayer insulating layer 109 corresponding to the second metal pattern 155 in the storage area StgA. The third metal pattern 157 can be connected to the first metal pattern 153 through a third contact hole 156 formed in the gate insulating layer 106 and the first and second interlayer insulating layers 108 and 109.

The first metal pattern 153 constitutes a second electrode (or top electrode) of a first storage capacitor C1 and constitutes a first electrode (or bottom electrode) of a second storage capacitor C2. The second metal pattern 155 constitutes a second electrode (or tope electrode) of a second storage capacitor C2 and constitutes a first electrode (or bottom electrode) of a third storage capacitor C3.

The gate insulating layer 106 disposed between the active pattern 151 and the first metal pattern 153 constitutes the first storage capacitor C1. The first interlayer insulating layer 108 disposed between the first metal pattern 153 and the second metal pattern 155 constitutes the second storage capacitor C2. The second interlayer insulating layer 109 disposed between the second metal pattern 155 and the third metal pattern 157 constitutes the third storage capacitor C3.

The light emitting diode D can be electrically connected to the thin film transistor DTr of the driving element in the pixel region P.

A passivation layer 117 is disposed on the source electrode 113, the drain electrode 115 and the third metal pattern 157, and covers the entire surface of the flexible substrate 101. The passivation layer 117 has a flat top surface and a drain contact hole (or a contact hole) 118 that exposes or does not cover the drain electrode 115 of the thin film transistor DTr. In one embodiment, the passivation layer 117 can comprise the same material as the gate insulating layer 106 and/or the first and second interlayer insulating layers 108 and 109. In another embodiment, the passivation layer 117 can comprise an organic material for planarization of the flexible substrate 101.

For example, the passivation layer 117 can comprise, but is not limited to, acrylic resins, epoxy resins, phenolic resins, polyamide-containing resins, polyimide-containing resins, unsaturated polyester resins, poly-phenylene-ether resins poly-phenylene-sulfide resins, benzocyclobutene and combination thereof. The passivation layer 117 can have a single-layered structure or a multiple-layered structure.

The light emitting diode (LED) D comprises a first electrode 210 that is disposed on the passivation layer 117 and connected to the drain electrode 115 of the thin film transistor DTr. The LED D further comprises an emissive layer 230 and a second electrode 220 each of which is disposed sequentially on the first electrode 210.

One of the first electrode 210 and the second electrode 220 can be an anode, and the other of the first electrode 210 and the second electrode 220 can be a cathode. One of the first electrode 210 and the second electrode 220 can be a reflective electrode, and the other of the first electrode 210 and the second electrode 220 can be a transmissive electrode.

The first electrode 210 is disposed separately in each pixel region P. In one embodiment, the first electrode 210 can be an anode and comprise conductive material having relatively high work function value. For example, the first electrode 210 can comprise a transparent conductive oxide (TCO).

In one embodiment, when the light emitting display device 100 is a bottom-emission type, the first electrode 210 can have a single-layered structure of the TCO. Alternatively, when the light emitting display device 100 is a top-emission type, a reflective electrode or a reflective layer can be disposed under the first electrode 210. For example, the reflective electrode or the reflective layer can comprise, but is not limited to, silver (Ag) or aluminum-palladium-copper (APC) alloy. As an example, in the LED D of the top-emission type, the first electrode 210 can have a triple-layered structure of ITO/Ag/ITO or ITO/APC/ITO.

In addition, a bank layer 119 is disposed on the passivation layer 117 in order to cover edges of the first electrode 210. The bank layer 119 exposes or does not cover a center of the first electrode 210 corresponding to each pixel region P. The first electrode 210 can have a structure separated for each pixel region P with the bank layer 119 as a boundary for each pixel region P.

In one embodiment, a spacer can be disposed on the bank layer 119. The spacer can be arranged to surround the bank layer 119 and can protect the light emitting layer 230 of the light emitting diode D from external pressure. The spacer can be formed of a composition containing one or more colorants, and can be composed of a black spacer with high light absorption to prevent color mixing of light.

The heat dissipater 160 extending outwardly form the first electrode 210 is disposed. The bank layer 119 can be disposed on the heat dissipater 160.

The emissive layer 230 is disposed on the first electrode 210. In one embodiment, the emissive layer 230 can have a single-layered structure of an emitting material layer (EML). In one embodiment, the EML can comprise organic emitting materials such as host and/or dopant. In another embodiment, the EML can comprise inorganic luminescent particles such as quantum dots (QDs) and/or quantum rods (QRs). For example, the organic dopant can comprise phosphorescent material, fluorescent material and/or delayed fluorescent material emitting red (R) color, green (G) color and blue (B) color. The LED D can emit white (W) color.

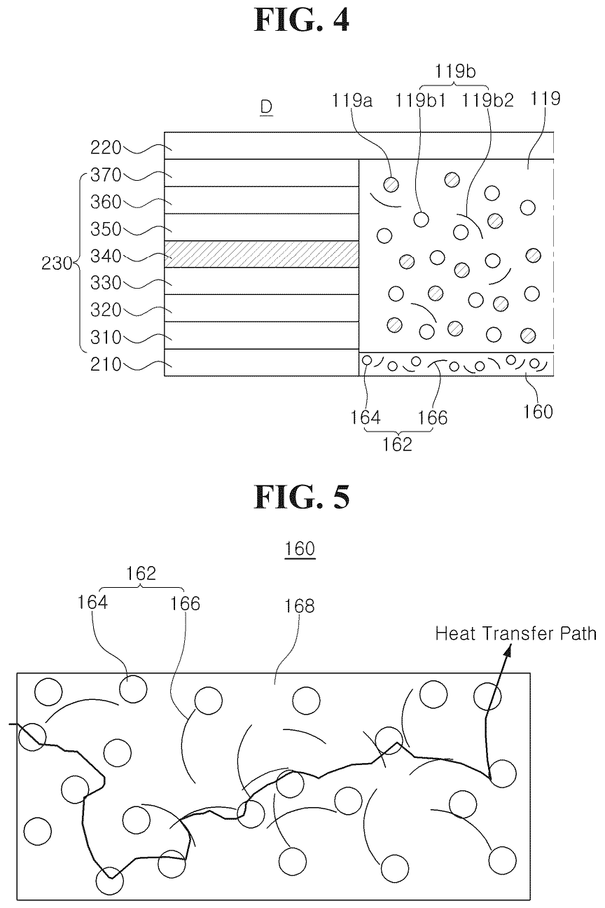

In another embodiment, the emissive layer 230 can have a multiple-layered structure. For example, the emissive layer 230 can further comprise a hole injection layer (HIL), a hole transport layer (HTL) and/or an electron blocking layer (EBL) disposed sequentially between the first electrode 210 and the EML, and/or a hole blocking layer (HBL), an electron transport layer (ETL), an electron injection layer (EIL) and/or a charge generation layer (CGL) disposed between the EML and the second electrode 210 (FIG. 4). Two or more emitting parts of the emissive layer 230 can form a tandem structure, or the emissive layer 230 can consist of a single emitting part (FIG. 4).

The second electrode 220 is disposed on the flexible substrate 101 above which the emissive layer 230 is disposed. The second electrode 220 can be disposed on the entire display area. The second electrode 220 can comprise a conductive material with a relatively low work function value compared to the first electrode 210. When the light emitting display device 100 is a top-emission type, the second electrode 220 is thin so as to have light-transmissive (semi-transmissive) property.

In addition, an adhesive layer can be disposed on the LED D in order to prevent or reduce outer moisture from penetrating into the LED D. The adhesive layer can comprise, but is not limited to, optically clear adhesive (OCA) and/or pressure sensitive adhesive (PSA).

In addition, an encapsulation film 170 can be disposed on the thin film transistor DTr and the LED D with covering the entire surface of the flexible substrate 101. For example, the encapsulation film 170 can have, but is not limited to, a laminated structure of a first inorganic insulating film 172, an organic insulating film 174 and a second inorganic insulating film 176. In certain embodiments, the encapsulation film 170 can be omitted.

A polarizer 180 can be disposed on the encapsulation film 170 to reduce reflection or contrast owing to external light in the top-emission type light emitting display device 100. The contrast of the light can be further improved by the polarizer 180 that blocks external light in a direction of the light emitted from the emissive layer 230.

In addition, a cover window can be attached to the encapsulation film 170 or the polarizer 180. In this case, the flexible substrate 101 and the cover window can have a flexible property, thus the light emitting display device 100 can be a flexible display device.

A trench TR can be disposed in the bending area B/A of the first non-display area NEA1 for bending the light emitting display device 100 with ease. The trench TR refers to a well-shaped depression in which portions of the multi-buffer layer 102, the active buffer layer 103, the gate insulating layer 106, and the first and second interlayer insulating layers 108 and 109 are removed. The light emitting display device 100 can be easily bent in the bending area B/A through the trench TR, and damages to the insulating films can be prevented.

Various thin films are stacked and patterned on the flexible substrate 101, and multiple insulating films 102, 103, 106, 108, and 109 can be continuously stacked. The bending stress in the laminated insulating films 102, 103, 106, 108, and 109 is different from the bending stress in the flexible substrate 101. Therefore, when the device 100 is severely or repeatedly bend and unfold it, the insulating films 102, 103, 106, 108 and 109 can be damaged due to the stress difference. As a result, separation can occur between the insulating films 102, 103, 106, 108, and 109, and elements interposed between the insulating films 102, 103, 106, 108, and 109 can be damaged. To prevent this, a portion of the insulating films 102, 103, 106, 108, and 109 are removed in advance to form a trench TR that partially exposes the surface of the flexible substrate 101, so that the stress damage to the insulating films can be prevented when bending stress is applied.

The trench TR can comprise wires 131 for connecting the thin film transistor DTr in the pixel region P and the pad portion 130 in the pad area PAD located on the first non-display area NEA1. The wires 131 can comprise metal material with beneficial conductivity. In one embodiment, the wires 131 can comprise the same metal as the source electrode 113 and/or the drain electrode 115 of the thin film transistor DTr. In another embodiment, the wires 131 can comprise the same metal as the gate electrode 107 of the thin film transistor DTr. However, the present disclosure is not limited thereto.

The wire 131 arranged in the bending area B/A is subjected to stress due to bending of the flexible substrate 101 compared to the wires GL, DL (FIG. 1) arranged in the pixel region P. Therefore, it is necessary that the wire 131 is designed to be robust against stress and have low resistance. In addition, the wire 131 must have sufficient flexibility to facilitate bending of the flexible substrate 101.

To this end, the wire 131 can have various shapes and structures. For example, the wire 131 can have a multi-layered structure in which a plurality of metal layers are stacked. As an example, the wire 131 can have, but is not limited to, multi layers each of which comprise Al, Ti, Mo, and/or Cu. An example of this combination is an aluminum layer sandwiched between titanium layers (Ti/Al/Ti), an aluminum layer sandwiched between upper and lower molybdenum layers (Mo/Al/Mo), and a copper layer sandwiched between titanium layers (Ti/Cu/Ti).), a copper layer (Mo/Cu/Mo) between the upper and lower molybdenum layers, etc. The wire 131 having such a multi-layered structure can maintain sufficient flexibility and can have beneficial conductivity since contact resistance between each metal layer is low.

The passivation layer 117 covering and protecting the thin film transistor DTr in the switching area TrA can be extended to prevent corrosion or damages to the wire 131. The pad portion 130 of the pad area PAD to which the wire 131 extending from the bending area B/A is connected comprises a first pad 133 comprising the same metal as the gate electrode 107, and a second pad 135 comprising the same material as the source electrode 113 and/or the drain electrode 115.

A fourth contact hole 136 that exposes or do not cover the first pad 133 is provided in the first and second interlayer insulating layers 108 and 109. The first pad 133 and the second pad 135 come into contact with each other through the fourth contact hole 136. In addition, the multi-buffer layer 102 and the active buffer layer 103 disposed under the first pad 133 can protect the first pad 133 and the second pad 135 from moisture and oxygen flowing from the bottom of the flexible substrate 101.

In addition, a color filter layer can be disposed on the LED D, or between the LED D and the flexible substrate 101 corresponding to the pixel region P. For example, when the pixel region P comprises the red (R) pixel region, the green (G) pixel region and the blue (B) pixel region, a red color filter, a green color filter and a blue color filter can be arranged correspondingly to the red (R) pixel region, the green (G) pixel region and the blue (B) pixel region, respectively.

In addition, a color conversion layer can be disposed between the LED D and the color filter layer. The color conversion layer can include a red color conversion layer, a green color conversion layer and a blue color conversion layer each of which is disposed correspondingly to each pixel region P, respectively, so as to convert the white (W) color light to each of a red, green and blue color lights, respectively. Alternatively, the light emitting display device 100 can comprise the color conversion layer instead of the color filter layer.

The configurations of the LED D disposed in the emission area of the pixel region P, the heat dissipater 160 extended outwardly from the first electrode 210 of the LED D, a portion of the first electrode 210 and the bank layer 119 covering the heat dissipater 160 will be described in more detail with referring to FIG. 4, which is a schematic drawing enlarging a portion “A” in FIG. 2.

As illustrate in FIG. 4, the light emitting diode D includes first and second electrodes 210 and 220 facing each other and an emissive layer 230 disposed between the first and second electrodes 210 and 220. One of the first electrode 210 and the second electrode 220 can be an anode, and the other of the first electrode 210 and the second electrode 220 can be a cathode. One of the first electrode 210 and the second electrode 220 can be a transmissive electrode, and the other of the first electrode 210 and the second electrode 220 can be a reflective electrode.

The first electrode 210 can comprise transparent conductive oxide (TCO) with relatively high work function. As an example, the first electrode 210 can comprise, but is not limited to, doped or undoped metal oxide such as indium-tin-oxide (ITO), indium-zinc-oxide (IZO), indium-tin-zinc-oxide (ITZO), indium-copper-oxide (ICO), tin oxide (SnO₂), indium oxide (In₂O₃), cadmium: zinc oxide (Cd: ZnO), fluorine: tin oxide (F: SnO₂), indium: tin oxide (In: SnO₂), gallium: tin oxide (Ga: SnO₂) and aluminum: zinc oxide (Al: ZnO; AZO). Alternatively or additionally, the first electrode 210 can comprise metal material or non-metal material such as nickel (Ni), platinum (Pt), gold (Au), silver (Ag), iridium (Ir) and/or carbon nanotube (CNT).

The second electrode 220 can comprise metal or metal halide with relatively low work function. As an example, the second electrode 220 can comprise, but is not limited to, calcium (Ca), barium (Ba), calcium/aluminum (Ca/Al), lithium fluoride/calcium (LiF/Ca), lithium fluoride/aluminum (LiF/Al), barium fluoride/aluminum (BaF₂/Al), cesium fluoride/aluminum (CsF/Al), calcium carbonate/aluminum (CaCO₃/Al), barium fluoride/calcium/aluminum (BaF₂/Ca/Al), aluminum (Al), magnesium (Mg), aluminum/magnesium (Al/Mg), gold: magnesium (Au: Mg) and/or silver: magnesium (Ag: Mg). For example, each of the first electrode 210 and the second electrode 220 can have a thickness of, but is not limited to, about 30 nm to about 300 nm.

The emissive layer 230 can comprise an emitting material layer (EML) 340. The emissive layer 230 can comprise at least one of a hole transport layer (HTL) 320 disposed between the first electrode 210 and the EML 340 and an electron transport layer (ETL) 360 disposed between the EML 340 and the second electrode 220. The emissive layer 230 can further comprise a hole injection layer (HIL) 310 disposed between the first electrode 210 and the HTL 320 and an electron injection layer (EIL) 370 disposed between the ETL 360 and the second electrode 220. Alternatively or additionally, the emissive layer 230 can further comprise at least one of an electron blocking layer (EBL) 330 disposed between the HTL 320 and the EML 340 and a hole blocking layer (HBL) 350 disposed between the EML 340 and the ETL 360.

The HIL 310 facilitates hole injections to the EML 340 from the first electrode 210. In certain embodiments, the HIL 310 can be omitted depending on the structure and/or the shape of the LED D.

HTL 320 transfers holes to the EML 340. The HTL can comprise organic material or inorganic material.

In one embodiment, the EML 340 can comprise organic emission material. For example, the EML 340 can comprise organic emission material emitting blue color, green color, red color, and optionally, yellow green color.

When the EML 340 comprises the organic emission material, the EML 340 can comprise a host and a blue dopant. The dopant can comprise at least one of phosphorescent material, fluorescent material and delayed fluorescent material.

In another embodiment, the EML 340 can comprise inorganic luminescent particles. For example, the inorganic luminescent particles can comprise nano inorganic luminescent particles such as quantum dots (QDs) and/or quantum rods (QRs). The QDs and/or QRs are nano inorganic particles that emit light as electrons in an unstable state fall from the conduction band energy level to the valence band energy level.

In one embodiment, the inorganic luminescent particles can have a single structure. In another embodiment, the inorganic luminescent particles can have a heterogeneous structure of core/shell, and can comprise plural organic ligands that are bound to the surface of the core or free from the inorganic luminescent particles. In this case, the shell can consist of one shell or comprise plural shells.

The ETL 360 transfers electrons to the EML 340. The ETL 360 can comprise organic material and/or inorganic material.

The EIL 370 facilitates electron injections from the second electrode 220 to the EML 340. In certain embodiment, the EIL 370 can be omitted depending upon the LED D property.

In FIG. 4, the LED D with one emitting part is illustrated. In another embodiment, the light emitting diode can have a tandem structure with multiple emitting parts. In this case, each emitting part can comprise one or more emitting material layers, and optionally, a hole injection layer, a hole transport layer, an electron blocking layer, a hole blocking layer, an electron transport layer and/or an electron injection layer. Emitting parts can be connected to each other through a charge generation layer. The charge generation layer can comprise a P-type charge generation layer and an N-type charge generation layer.

The heat dissipater 160 disposed under the bank layer 119 is extended outwardly from the first electrode 210. The heat dissipater 160 can comprise a first heat dissipating particle 162. The first heat dissipating particle 162 can be a white dissipating particle. For example, the first heat dissipating particle 162 can comprise a first nano heat dissipating particle 164 with a zero-dimensional shape and/or a second nano heat dissipating particle 166 with one dimensional, two dimensional or three dimensional shape. As an example, the first heat dissipating particle 162 can be dispersed in a binder resin 168 (FIG. 5).

As described below, the heat dissipater 160 can be extended to the pad portion 130 or the driver 120 each of which is disposed in the first non-display area NEA1 of the light emitting display device 100 (FIGS. 2 and 3). Heat transfer pathway (FIG. 5) in the heat dissipater 160 comprising the first heat dissipating particle 162 can be generated. Heat generated in the LED D and/or the bank layer 119 can be discharged outwardly through the heat dissipater 160 extending outwardly from the first electrode 210. The driving stability of the light emitting display device 100 can be improved.

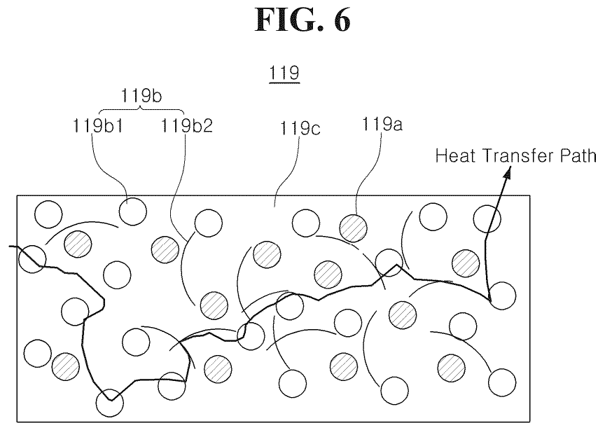

The bank layer 119 covering the edge of the first electrode 210 and defining each pixel region P can comprise a light absorbing material 119a and/or a second heat dissipating particle 119b. The second heat dissipating particle 119b can be a white heat dissipating particle. For example, the second heat dissipating particle 119b can comprise a first nano heat dissipating particle 119b1 with a zero-dimensional shape and/or a second nano heat dissipating particle 119b2 with one dimensional, two dimensional or three dimensional shape. As an example, the light absorbing material 119a and the second heat dissipating particle 119b can be dispersed in a binder resin 119c (FIG. 6).

For example, the binder resin in which the first heat dissipating particle 162 or the second heat dissipating particle 119b is dispersed can be dissolved in an alkaline soluble aqueous solution, and can have one or more thermosetting functional groups (e.g., acrylate group, methacrylate group, vinyl group, etc.).

When the bank layer disposed in the non-emission area of each pixel region P consists only the light absorbing material 119a, processibility problems such as micro patterns and residues can be arises owing to the high contents of the light absorbing material 119a. In addition, problems arise in terms of outgassing and reliability due to by-products added in addition to the light absorbing material 119a. Further, it is difficult to suppress the fundamental reflectance due to the surface reflection caused by the differences in refractive index even if the bank layer 119 consists only of the light absorbing material 119a.

On the other hand, the bank layer 119 includes white second heat dissipating particle 119b in addition to the light absorbing material 119a. Since the contents of the light absorbing material 119a in the bank layer 119 can be reduced, the stability and reliability of the process caused by using high contents of the light absorbing material can be improved, and the generation of outgas can be suppressed.

In addition, a heat transfer path is formed among the second heat dissipation particle 119b within the bank layer 119 comprising the second heat dissipation particles 119b (FIG. 6). Accordingly, heat generated in driving the light emitting diode D can be emitted through the bank layer 119.

The bank layer 119 with relatively large surface area includes the second heat dissipating particle 119b. Accordingly, it can be effective in reducing heat in the entire light emitting display device 100 similar to applying the heat dissipating material to the flexible substrate 101 (FIG. 3). The luminous lifetime of the light emitting display device 100 can be improved by suppressing deterioration of various materials included in the light emitting display device 100.

In one embodiment, the light absorbing material 119a and the second heat dissipating particle 119b can be mixed, but is not limited to, with a weight ratio of about 8:2 to about 2:8, for example, about 5:5 to about 2:8. When the bank layer 119 includes the second heat dissipating particle 119b as well as the light absorbing material 119a, the reflectivity of the light emitting display device 100 can be improved, comparing in case the bank layer 119 consists only of the light absorbing material. In another embodiment, the light absorbing material 119a and the second heat dissipating particle 119b in the bank layer 119 can be mixed, but is not limited to, with a weight ratio of about 4:6 to about 1:9, about 3:7 to about 1:9 or about 2:8 to about 1:9.

In one embodiment, the light absorbing material 119 can comprise one or more black colorants such as one or more black pigments and/or one or more black dyes. In another embodiment, the light absorbing material 119a can comprise, but is not limited to, carbon black, carbon nanotube (CNT), graphene, organic black, black dyes, azo-type dyes or pigments, carbon materials, hybrid type of R/G/G pigments/dyes, multi-layered thin film material. Alternatively, any organic material that is oxidized after photoresist process comprising exposures and development processes, or in the course of post-baking process of the bank layer, and converted to black color can be used as the light absorbing material 119a.

The heat dissipation path in the heat dissipater 160 comprising the first heat dissipating particle 162 and the bank layer 119 comprising the second heat dissipating particle 119b will be described. FIG. 5 is a diagram illustrating schematically heat transfer path in a heat dissipater in accordance with one embodiment of the present disclosure.

As illustrated in FIG. 5, the heat dissipater 160 includes the first heat dissipating particle 162 dispersed in a binder resin 168. For example, the binder resin 168 can comprise one or more polymers used in the electro-spinning process. As an example, the first heat dissipating particle 162 comprise a first nano heat dissipating particle 164 with a zero dimensional shape, a second nano heat dissipating particle 166 with a one dimensional, two dimensional or three dimensional shape, or any combination thereof.

For example, the first nano heat dissipating particle 164 can comprise a nanoparticle. The second nano heat dissipating particle 166 can comprise a nanotube with one dimensional shape, a nanowire and/or a nanosheet with a two dimensional shape and a nano particle with a three dimensional shape such as a hexagonal shape and/or a cubic shape. With referring to FIG. 5, when the heat dissipater 160 includes the second nano heat dissipating particle 166 with the one dimensional, two dimensional and/or three dimensional shapes, the heat transfer path outward can be effective formed within the heat dissipater 160 through the network structure within the second nano heat dissipating particle 166.

FIG. 6 is a diagram illustrating schematically heat transfer path in a bank layer in accordance with another embodiment of the present disclosure.

As illustrated in FIG. 6, the bank layer 119 comprise the light absorbing material 119a and the second heat dissipating particle 119b dispersed in a binder resin 119c. As an example, the second heat dissipating particle 119b can comprise the first nano heat dissipating particle 119b1 with a zero dimensional shape, the second nano heat dissipating particle 119b2 with one to three dimensional shape, or any combination thereof.

For example, the first nano heat dissipating particle 119b1 can comprise a nanoparticle. The second nano heat dissipating particle 119b2 can comprise a nanotube with one dimensional shape, a nanowire and/or a nanosheet with a two dimensional shape and a nano particle with a three dimensional shape such as a hexagonal shape and/or a cubic shape. With referring to FIG. 6, when the bank layer 119 includes the second nano heat dissipating particle 119b2 with the one dimensional, two dimensional and/or three dimensional shapes, the heat transfer path outward can be effective formed within the bank layer 119 through the network structure within the second nano heat dissipating particle 119b2.

In another embodiment, each of the first heat dissipating particle 162 and the second heat dissipating particle 119b can independently comprise metal material, carbon-containing material, ceramic material and/or combination thereof. As an example, each of the first heat dissipating particle 162 and the second heat dissipating particle 119b can independently comprise, but is not limited to, any one of metal material of gold (Au), copper (Cu), silver (Ag), or any combination thereof; carbon-containing material of graphite, graphene, carbon nanotube (CNT), or any combination thereof; any one inorganic oxide material of Al₂O₃, SiO₂, MgO, ZnO, ZrO₂, or any combination thereof; any one inorganic nitride of AlN, boron nitride (BN), or any combination thereof; boron arsenide (BAs); or any combination thereof.

In one embodiment, each of the first heat dissipating particle 162 and the second heat dissipating particle 119b can independently comprise boron nitride (BN). Boron nitride (BN) is referred to as white graphene, and consists of boron with a similar structure to graphene and nitrogen (N). On the contrary, boron nitride (BN) is an electrical insulation since no free electron is present unlikely to graphene, and has very excellent thermal conductivity owing to electron-phonon interaction.

In addition, boron nitride (BN) has very beneficial scattering property because boron nitride (BN) has very high refractive indices (e.g., hexagonal boron nitride (h-BN) has refractive index of about 1.8, cubic boron nitride (cBN) has refractive index of about 2.1). Accordingly, it is possible to control the reflectivity in the light emitting display device by applying boron nitride (BN) as the first heat dissipating particle 164 and/or the second heat dissipating particle 119b. In addition, boron nitride (BN) has beneficial thermal conductivity as metal and excellent thermal dissipation property.

As an example, each of the first heat dissipating particle 162 and the second heat dissipating particle 191b can independently be, but is not limited to, any one of boron nitride nanotube (BNNT), born nitride nanowire, boron nitride nanosheet (BNNS), hexagonal boron nitride (h-BN), cubic boron nitride (c-BN) and/or combinations thereof.

In another embodiment, each of the first heat dissipating particle 162 and the second heat dissipating particle 119b can independently be, but is not limited to, any one of a nanoparticle, a nanotube, a nanowire, a nanosheet and/or combinations thereof. For example, each of the first heat dissipating particle 162 and the second heat dissipating particle 119b can independently comprise, but is not limited to, any one of a boron nitride nanoparticle, a boron nitride nanotube, a boron nitride nanowire, a born nitride nanosheet and/or combinations thereof.

In another embodiment, each of the first heat dissipating particle 162 and the second heat dissipating particle 119b can comprise, but is not limited to, a nanoparticle, and at least one of a nanowire and a nanosheet. Compared to the sole use of zero-dimensional nanoparticle (e.g., nanoparticle such as boron nitride nanoparticle) without an aspect ratio (height/line width), the thermal dissipation property in the bank layer 119b and/or the heat dissipater 160 can be further improved in case of using a nanowire (e.g., boron nitride nanowire) and/or a nanosheet (e.g., boron nitride nanosheet), which are one-dimensional material with an aspect ratio.

For example, each of the nanowire and the nanosheet, which can be applied as the first heat dissipating particle 162 and/or the second heat dissipating particle 119b, can have an aspect ratio of about 100 to about 10,000, for example, about 300 to about 5000, about 300 to about 1000, or about 300 to about 500.

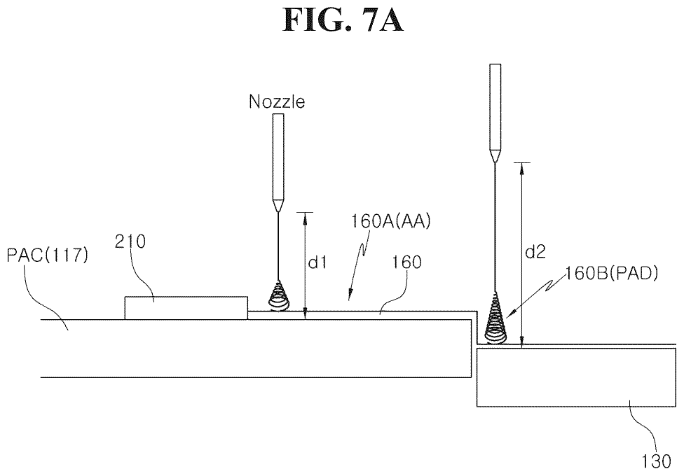

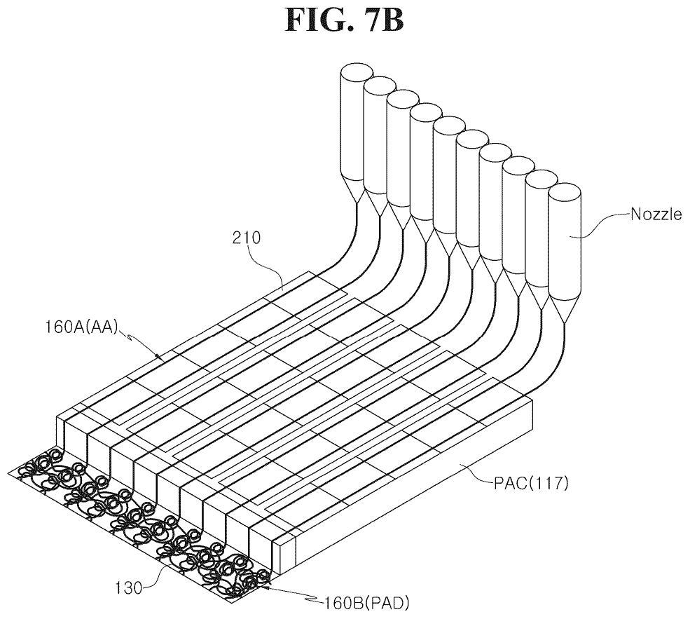

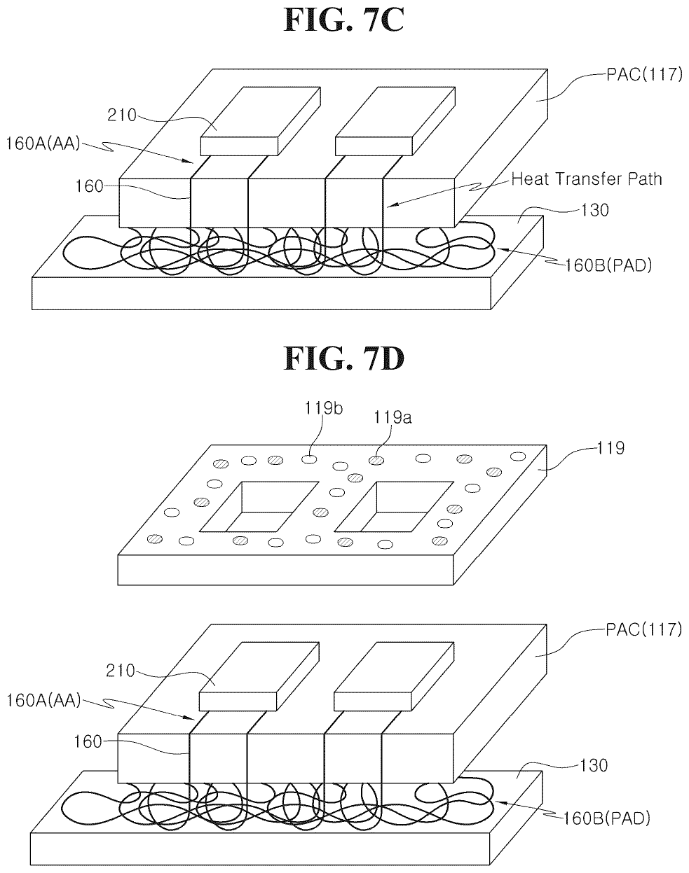

The process of fabricating the heat dissipater 160 will be described. FIGS. 7A to 7D illustrate a process of disposing the heat dissipater extending outwardly from a first electrode of the light emitting diode using an electrospinning process in accordance with an embodiment of the present disclosure.

As illustrated in FIG. 7A, the first electrode 210 is disposed on the passivation layer 117 or PNA for each pixel region P (FIGS. 2 and 3). The heat dissipater 160 can be fabricated using electro-spinning process. Electro-spinning solution comprising the second heat dissipating particle 162 (FIG. 4) is electrically sprayed outwardly using the nozzle. As the electro-spinning solution becomes solidified, the heat dissipater 160 comprising the first heat dissipating particle 162 can be extended outwardly from the first electrode 210 to the pad portion 130 in the first non-display area NEA1 (FIG. 3), so that the heat dissipater 160 with the heat transfer path can be disposed outwardly from the outside of the first electrode 210. The nanofiber shaped heat dissipater 160 is disposed in the area other than the first electrode 210 through the electro-spinning process for flattening the surface of the first electrode 210.

In this case, the distance d1 between the nozzle and the passivation layer 170 or PAC in the area close to the first electrode 210 is set to be relatively short, and the distance d2 between the nozzle and the passivation layer 170 or PAC in the area close to the pad portion 130 is set to be relatively long (d1<d2). As the distance d2 between the nozzle and the target substrate is long in the electro-spinning process, nanofibers with a random arrangement are arranges. As the distance d1 between the nozzle and the target substrate is short, nanofibers with a linear shape can be arranged similar to a general printing process.

Accordingly, as illustrated in FIGS. 7B and 7C, the heat dissipater 160A in the form of a nanofiber with linear shape is disposed in the area close to the first electrode 210 where the electro-spinning process was performed with the distance d1 between the nozzle and the passivation layer 170 is set to relatively short, for example, in the active area AA comprising the pixel region P. On the other hand, the heat dissipater 160B in the form of a nanofiber with a random arrangement is disposed in the area where the electro-spinning process was performed with the distance d2 between the nozzle and the passivation layer 170 is set to relatively long, for example, in the pad 130 within the pad portion PAD.

The heat dissipater 160A with a linear shape is disposed in the area close to the first electrode 210, and the bank layer 119 is disposed on the heat dissipater 160A with the linear shape. The heat transfer path was formed in the heat dissipater with the linear shape. The heat generated in the light emitting diode D comprising the first electrode 210 and the bank layer 119 can be dissipated to the pad area PAD through the heat dissipater 160A with the linear shape.

On the other hand, the heat dissipater 160B with a random arrangement is disposed in the pad area PAD. In other words, the heat dissipater 160B disposed in the pad area PAD has a more densely intertwined structure compared to the heat dissipater 160A with the linear shape disposed in the area close to the first electrode 210. As the mechanical properties of the pad area PAD improves, stresses against various bending directions can be effectively alleviated. The heat dissipater 160B disposed in the pad area PAD can be connected to a back-plate and a heat sink in a later process, and ultimately dissipates heat to the outside.

As illustrated in FIG. 7D, the bank layer 119b comprising the light absorbing material 119a and the second heat dissipating particle 119b can be patterned with covering the periphery of the first electrode 210 and the heat dissipater 160. For example, the heat dissipater 160 fabricated by the electro-spinning process can have a diameter, but is not limited to, about 50 nm to about 1000 nm, and the electro-spinning process can be performed for about 1 to about 10 minutes, but is not limited thereto.

The heat dissipater can be fabricated by a printing method. FIGS. 8A and 8B illustrate a process of disposing the heat dissipater extending outwardly from the first electrode of the light emitting diode using a printing process in accordance with another embodiment of the present disclosure.

As an example, as illustrated in FIG. 8A, the heat dissipater 160 comprising the first heat dissipating particle 162 is extended outwardly from the first electrode 210. As an example, when the first heat dissipating particle 162 includes the second nano heat dissipating particle 166 (FIG. 5) such as the nanotube with a one-dimensional shape, the nanowire and/or the nanosheet with a two-dimensional shape and/or the nanoparticle with a three-dimensional shape, the heat transfer path directing outwardly of a nano channel shape can be generated within the first heat dissipating particle 162.

In one embodiment, the heat dissipater 160 is extended close to the driver 120 in the first non-display area NEA1 (FIGS. 2 and 3) in FIG. 8A, In this case, heat dissipating adhesive 164 can be interposed between one end of the heat dissipater and the inner face of the driver 120. Next, as illustrated in FIG. 8B, the light emitting diode is disposed in the emission area of the pixel region P by laminating the emissive layer 230 and the second electrode 220 on the first electrode 210. The bank layer 190 is patterned in the non-emission area among the emission areas of the pixel region with covering the periphery of the first electrode 210 and the heat dissipater 160.

The heat dissipater 160 is extended from one outside of the first electrode 210 to the driver 120 in FIGS. 8A and 8B. In another embodiment, the heat dissipater 160 can be extended outwardly from the first electrode 210 to the pad 130, as illustrated in FIGS. 7A to 7D.

The heat dissipater 160 comprising the first heat dissipating particle 162 is extended outwardly from the first electrode 210 constituting the light emitting diode D, and the bank layer 119 disposed adjacently to the light emitting diode D includes the second heat dissipating particle 119b as well as the light absorbing material 119a. As the contents of the light absorbing material 119a in the bank layer 119 decreases, the process reliability and stability for the bank layer 119 can be secured.

The deteriorations of materials in the light emitting display device 100, comprising luminous materials included in the light emitting diode D, owing to heat generate in the light emitting display device 100 can be prevented or minimized. The luminous lifetime of the light emitting diode D and the light emitting display device can be significantly improved.

### Example 1 (Ex. 1): Preparation of Bank Layer with Heat Dissipating Particles

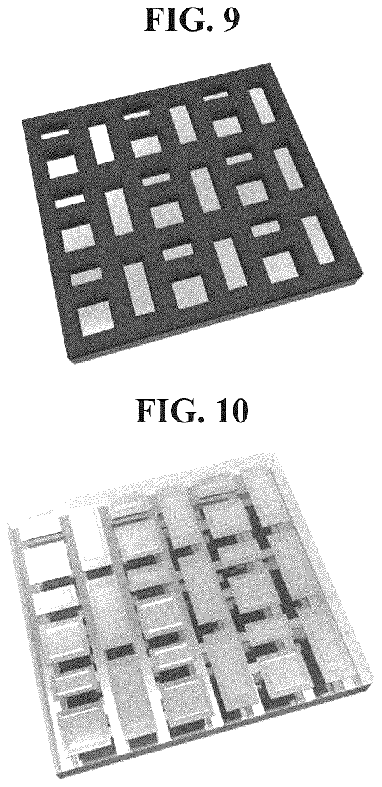

A colorant composition comprising a polymer of a binder of 40 parts by weight, zero-dimensional boron nitride nanoparticles of white particles of 2.5 parts by weight, one-dimensional boron nitride of 0.5 parts by weight and a black pigment of 2 parts by weight is coated on a patterned anode. Patterned gray bank layer was prepared by photoresist process. The prepared gray patterned bank is illustrated in FIG. 9.

### Comparative Example 1 (Ref. 1): Preparation of Transparent Bank Layer

Transparent bank layer was prepared using a composition comprising a polymer of a binder of 45 parts by weight without any colorant. The prepared transparent patterned bank is illustrated in FIG. 10.

### Comparative Example 2 (Ref. 2): Preparation of Black Bank Layer

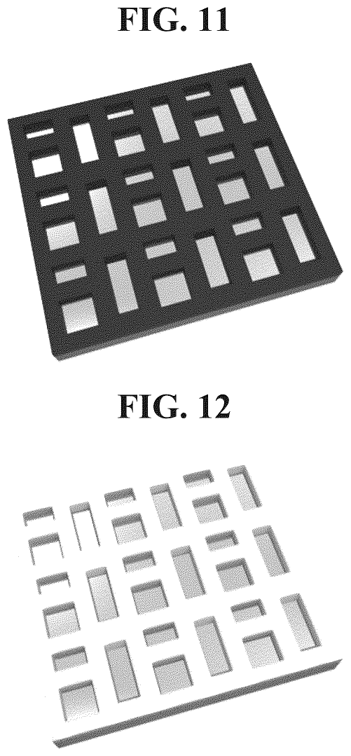

Black bank layer was prepared using a composition comprising a polymer of a binder of 45 parts by weight and a black pigment of 10 parts by weight. The prepared black patterned bank is illustrated in FIG. 11.

### Comparative Example 3 (Ref. 3): Preparation of White Bank Layer

White bank layer was prepared using a composition comprising a polymer of a binder of 20 parts by weight and a nanoparticle of a white particle of 25 parts by weight. The prepared white patterned bank is illustrated in FIG. 12.

### Experimental Example 1: Measurement of Transparency and Reflectivity of Bank Layer

The transparency (450 nm) and reflectivity (550 nm) for each of the bank layers prepared in Example 1 and Comparative Examples 1-3 were measured. The following Table 1 illustrates measurement results.

TABLE 1
Measurement of Transparency and Reflectivity of Bank Layer

| Sample | Ref. 1 | Ref. 2 | Ref. 3 | Ex. 1 |
|---|---|---|---|---|
| Transparency (%) | 91.6 | 0.12 | 9.60 | 0.63 |
| Reflectivity (%) | 8.0 | 5.2 | 77.7 | 50.8 |

### Experimental Example 2: Simulation of Optical Reflectivity of Light Emitting Display Device

The reflectivity, SCI (Specular Component Included) and SCE (Specular Component Excluded) of a light emitting display device were simulated using ExpertOLED when a bank layer comprising boron nitride and a black pigment. The thickness of each layer in the light emitting diode was set as indicated in the following Table 2. For the Film structure, the surface of the bank layer was designed to be flat, and for the Rough structure, Ra of the bottom surface of the bank layer was set to be 7.9 nm. The incident light had a 100% radio wave length and an incidence angle of 8 degree, and SCE excluded −10 to 10° reflection area. B:W ration was designed considering the reflective index (n) and attenuation coefficient (K) of the black pigment and boron nitride (BN), and the initial optical density (O.D.) was designed to be 1.5.

TABLE 2
Composition and Thickness of Light Emitting Diode

| | Thickness (nm) | Note |
|---|---|---|
| Air | 3500 | Air |
| SiNₓ | 1200 | Encap. |
| MgAg | 15 | Cathode |
| ETL | 90 | EL |
| EML_Blue | 20 | |
| HTL | 90 | |
| Simulation layer | 1500 | Bank Layer |
| | | (Transparent/Black/White/Gray) |
| ITO | 7 | Anode |
| Ag | 100 | |
| ITO | 7 | |
| PAC | 2300 | PLN |
| Ag | 200 | TFT electrode replacement |
| Glass | 1000 | Substrate Glass |
| Air | 471 | Air |
| Total | 10500 | |

SCI and SCE evaluation results by the colors of the bank layer and the bottom structure of the bank layer in the organic light emitting diode designed in Table 2 are illustrated in the following Table 3.

TABLE 3
Reflectivity of Organic Light Emitting Diode

| Sample | SCI | SCE | Note |
|---|---|---|---|
| Transparent Bank | 77.6% | 37.2% | Film Structure |
| Layer | | | |
| Black Bank Layer | 6.2% | 0.03% | Film Structure |
| Black Bank Layer | 6.4% | 0.04% | Rough Structure |
| White Bank Layer | 76.5% | 71.3% | Film Structure |
| White Bank Layer | 79.8% | 76.8% | Rough Structure |
| Gray Bank Layer 1 | 8.3% | 0.74% | Rough Structure (B:W = 8:2) |
| Gray Bank Layer 2 | 16.4% | 3.27% | Rough Structure (B:W = 5:5) |
| Gray Bank Layer | 46.7% | 34.6% | Rough Structure (B:W = 2:8) |

As illustrated in Table 3, the reflectivity of the organic light emitting diode can be controlled by varying the combination of the black material and white heat dissipating material in the bank layer.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. A light emitting display device, comprising:
a substrate having an active area comprising a pixel region, and a non-display area adjacent to the active area;
a thin film transistor disposed in the pixel region on the substrate;
a light emitting diode comprising a first electrode connected to a drain electrode of the thin film transistor; and
a heat dissipater extended outwardly from the first electrode,
wherein the heat dissipater comprises a first heat dissipating particle.

2. The light emitting display device of claim 1, wherein the first heat dissipating particle comprises any one of the following:
a metal material among gold (Au), copper (Cu), silver (Ag), or any combination thereof;
a carbon-containing material among graphite, graphene, carbon nanotube (CNT), or any combination thereof;
any one inorganic oxide material among Al₂O₃, SiO₂, MgO, ZnO, ZrO₂, or any combination thereof;
any one inorganic nitride among aluminum nitride (AlN), boron nitride (BN), or any combination thereof;
boron arsenide (BAs); or
any combination thereof.

3. The light emitting display device of claim 1, wherein the first heat dissipating particle comprises boron nitride.

4. The light emitting display device of claim 1, wherein the first heat dissipating particle comprises any one of boron nitride nanotube (BNNT), boron nitride nanowire, boron nitride nanosheet (BNNS), hexagonal boron nitride (h-BN), cubic boron nitride (c-BN), or any combination thereof.

5. The light emitting display device of claim 1, wherein the first heat dissipating particle comprises any one of a nanoparticle, a nanotube, a nanowire, a nanosheet, or any combination thereof.

6. The light emitting display device of claim 5, wherein the first heat dissipating particle comprises the nanoparticle, and at least one of the nanowire and the nanosheet.

7. The light emitting display device of claim 5, wherein each of the nanowire and the nanosheet has an aspect ratio of about 100 to about 10,000.

8. The light emitting display device of claim 1, wherein the light emitting display device further comprises a bank layer surrounding a periphery of the first electrode for each pixel region.

9. The light emitting display device of claim 8, wherein the bank layer comprises a light absorbing material and a second heat dissipating particle.

10. The light emitting display device of claim 9, wherein the light absorbing material and the second heat dissipating particle in the bank layer are mixed with a weight ratio between about 8:2 and about 2:8.

11. The light emitting display device of claim 9, wherein the second heat dissipating particle comprises any one of metal material of gold (Au), copper (Cu), silver (Ag), or any combination thereof; carbon-containing material of graphite, graphene, carbon nanotube (CNT), or any combination thereof; any one inorganic oxide material of Al₂O₃, SiO₂, MgO, ZnO, ZrO₂, or any combination thereof; any one inorganic nitride of AlN, boron nitride (BN), or any combination thereof; boron arsenide (BAs); or any combination thereof.

12. The light emitting display device of claim 9, wherein the second heat dissipating particle comprises boron nitride.

13. The light emitting display device of claim 9, wherein the second heat dissipating particle comprises any one of boron nitride nanotube (BNNT), boron nitride nanowire, boron nitride nanosheet (BNNS), hexagonal boron nitride (h-BN), cubic boron nitride (c-BN), or any combination thereof.

14. The light emitting display device of claim 9, wherein the second heat dissipating particle comprises any one of a nanoparticle, a nanotube, a nanowire, a nanosheet, or any combination thereof.

15. The light emitting display device of claim 14, wherein the second heat dissipating particle comprises the nanoparticle, and at least one of the nanowire and the nanosheet.

16. The light emitting display device of claim 14, wherein each of the nanowire and the nanosheet has an aspect ratio of about 100 to about 10,000.

17. The light emitting display device of claim 1, wherein the heat dissipater is extended to a pad portion disposed in the non-display area from an outside of the first electrode.

18. The light emitting display device of claim 17, wherein the heat dissipater is extended outwardly in a linear form in the active area of the outside of the first electrode, and is randomly disposed in a pad area comprising the pad portion.

19. The light emitting display device of claim 1, wherein the heat dissipater is extended toward a driver disposed in the non-display area from an outside of the first electrode, and a heat dissipating adhesive is interposed between an end of the heat dissipater and the driver.

20. The light emitting display device of claim 1, wherein the light emitting diode further comprises:
a second electrode facing the first electrode; and
an emissive layer disposed between the first electrode and the second electrode,
wherein the emissive layer comprises one or more emitting material layers.
